(19) United States
(12) Patent Application Publication
(10) Pub. No.: US 2019/0096927 A1
(43) Pub. Date: Mar. 28, 2019

(54) MANUFACTURING METHOD OF THIN FILM TRANSISTOR AND MASK

(71) Applicant: WUHAN CHINA STAR OPTOELECTRONICS TECHNOLOGY CO., LTD, Wuhan, Hubei (CN)

(72) Inventors: Qi DING, Shenzhen, Guangdong (CN); Zhandong ZHANG, Shenzhen, Guangdong (CN); Li WANG, Shenzhen, Guangdong (CN)

(21) Appl. No.: 15/744,174

(22) PCT Filed: Nov. 24, 2017
(86) PCT No.: PCT/CN2017/112848

§ 371 Date: May 1, 2018

(30) Foreign Application Priority Data
Sep. 28, 2017 (CN) 201710899582.5

(51) Int. Cl. H01L 27/12; H01L 21/027; H01L 21/266; H01L 29/66; H01L 29/786; G03F 1/32

(52) U.S. Cl. CPC H01L 27/1296; H01L 21/0274; H01L 21/266; H01L 27/1222; H01L 27/127; G03F 7/16; H01L 29/66492; H01L 29/66757; H01L 29/78621; H01L 29/78675; G03F 1/32; H01L 27/1288

(57) ABSTRACT

A manufacturing method of a thin film transistor is provided, which comprising the steps of: providing a substrate which includes a film layer; coating a photoresist material on the film layer to form a photoresist layer; executing an exposure process to the photoresist layer by using a mask, wherein the mask includes a central region and a boundary region surrounding the central region, a thickness of the central region is greater than that of the boundary region, and by having the thickness of the central region greater than that of the boundary region during the exposure process applied to the photoresist layer, loading effect happened during the development process is cancelled to uniformize a thickness of the film layer. A mask, a thin film transistor, and a display device are also provided in the present invention.

### RELATED APPLICATIONS

The present application is a National Phase of International Application Number PCT/CN2017/112848, filed Nov. 24, 2017, and claims the priority of China Application No. 201710899582.5, filed Sep. 28, 2017.

### FIELD OF THE DISCLOSURE

The present invention is related to display technology, and more particularly is related to a manufacturing method of a thin film transistor, a mask, a thin film transistor, and a display device.

### BACKGROUND

In present, the technology for manufacturing a low temperature polysilicon thin film transistor (LTPS-TFT) in general is as follows. After using a mask to apply the corresponding exposure and development treatments to the photoresist layer (PR), an ion implantation process is carried out to implant high concentration phosphorus (P) ions, i.e. the N+ ions, into the source electrode and the drain electrode to form N+ p-Si regions as the ohmic contact and the length of lightly-doped-drain (LDD) is also decided in the step, and then the photoresist layer (PR) is stripped after an ashing treatment to complete the manufacturing process.

The photoresist development process is carried out by using a liquid developer solution, but the photoresist layer (PR) at the central cross of the substrate is not treated by the photoresist development process. Thus, the cross region may suffer the loading effect, i.e. the developer solution in the central region has a higher concentration, which may generate a greater change to the position of the N-type TFT highly doped film to result in a smaller line width in compared with the regions away from the central region such that problems of uniformity anomaly and electric anomaly of product yield would be resulted.

### SUMMARY

In order to resolve the aforementioned problems of uniformity anomaly and electric anomaly of product yield due to the nonuniform film change, a thin film transistor and a manufacturing method thereof is provided in accordance with the embodiments of the present invention.

In accordance with a first aspect of the present invention, a manufacturing method of a thin film transistor is provided. The manufacturing method comprises the steps of: providing a substrate which includes a film layer; coating a photoresist material on the film layer to form a photoresist layer; and executing an exposure process to the photoresist layer by using a mask, wherein the mask includes a central region and a boundary region surrounding the central region, and a thickness of the central region is greater than that of the boundary region. The mask includes four sub-masks placed in an array to form a central cross therebetween. The central region includes regions of the four sub-masks corresponding to a center of the central cross. The boundary region is divided into four sub-regions by the central cross. By having the thickness of the central region greater than that of the boundary region during the exposure process applied to the photoresist layer, loading effect happened during a development process is cancelled to uniformize a thickness of the film layer.

In accordance with an embodiment of the manufacturing method of the present invention, the central region of the mask is opaque, and the boundary region of the mask is transparent.

In accordance with an embodiment of the manufacturing method of the present invention, transmittance of the boundary region of the mask is greater than 0.2 and small than 0.6.

In accordance with an embodiment of the manufacturing method of the present invention, the manufacturing method further comprises the steps of developing, ashing, and striping the film layer after the exposure process.

In accordance with an embodiment of the manufacturing method of the present invention, the film layer is formed by using a half-tone mask.

In accordance with an embodiment of the manufacturing method of the present invention, the thickness difference between the central region and the boundary region of the mask is changed based on the variation of transmittance in mask design.

In accordance with a second aspect of the present invention, a mask is provided. The mask comprises a central region and a boundary region surrounding the central region, wherein a thickness of the central region is greater than that of the boundary region. The mask includes four sub-masks placed in an array to form a central cross therebetween. The central region includes regions of the four sub-masks corresponding to a center of the central cross. The boundary region is divided into four sub-regions by the central cross. By having the thickness of the central region greater than that of the boundary region during an exposure process applied to the photoresist layer, loading effect during an development process is cancelled to uniformize a thickness of the film layer.

In accordance with an embodiment of the mask of the present invention, the central region of the mask is opaque, and the boundary region of the mask is transparent.

In accordance with an embodiment of the mask of the present invention, transmittance of the boundary region of the mask is greater than 0.2 and small than 0.6.

In accordance with a third aspect of the present invention, a thin film transistor formed by using the aforementioned manufacturing methods is provided.

Wherein, the source electrode is in contact with the surface of the low temperature poly-silicon layer away from the buffer layer through the source contact region, and the drain electrode is in contact with the surface of the low temperature poly-silicon layer away from the buffer layer through the drain contact region.

In accordance with a fourth aspect of the present invention, a display device which comprises the thin film transistor described in the third aspect of the present invention is provided.

The advantage of the present invention is as follows.

The manufacturing method of the thin film transistor provided in the present invention adopts the half-tone technology to have the thickness of the central region of the mask different from that of the boundary region of the mask, and the central region is opaque and the boundary region is transparent. Because a thicker photoresist layer needs a developer solution with a higher concentration, in the present invention, the loading effect happened during the development process can be exactly cancelled by the thicker photoresist layer, i.e. the developer solution in the central cross has a higher concentration to synchronize the development speed of the central region and the boundary region within the same development period so as to guarantee the uniformity of the film layer on the substrate, and thus the problems of uniformity anomaly and electric anomaly of product yield can be prevented.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts.

FIG. 1 is a flow chart showing the manufacturing method of the thin film transistor provided in accordance with an embodiment of the present invention.

FIG. 2 is a structural schematic view of the mask provided in accordance with an embodiment of the present invention.

FIG. 3 is a structural schematic view of the substrate after the exposure treatment in accordance with an embodiment of the present invention.

FIG. 4 is a structural schematic view showing the thin film transistor provided by using the manufacturing method in accordance with an embodiment of the present invention.

FIG. 5 is a top view of the film layer formed on the substrate by using the mask provided in accordance with an embodiment of the present invention.

FIG. 6 is a structural schematic view of the substrate after the exposure treatment by using the conventional technology.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

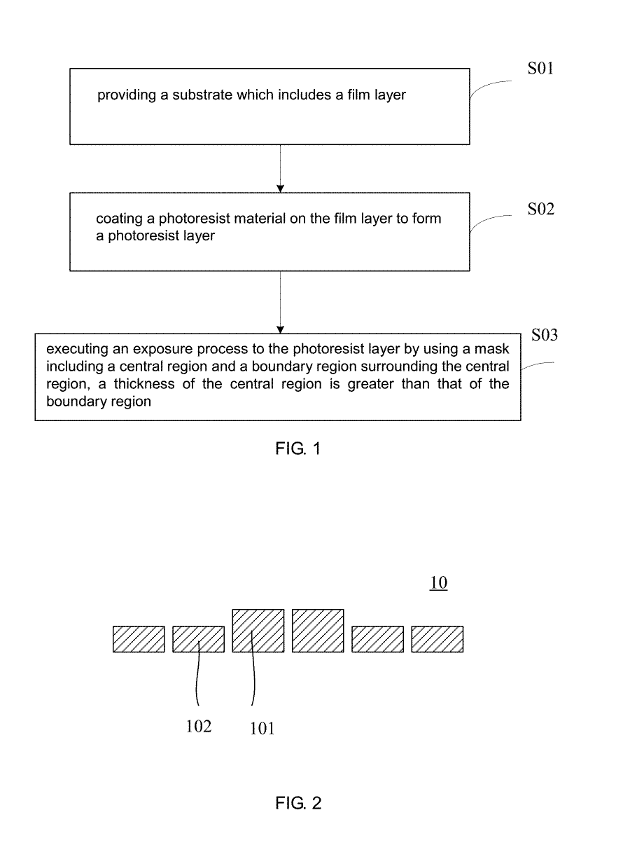

FIG. 1 is a flow chart showing the manufacturing method of the thin film transistor provided in accordance with an embodiment of the present invention, and FIG. 4 is a structural schematic view showing the thin film transistor provided by using the manufacturing method in accordance with an embodiment of the present invention. As shown in FIG. 1 and FIG. 4, the manufacturing method comprises the following steps.

Step S01 is to provide a substrate 1 and from a buffer layer 2, a low temperature poly-silicon layer 3, a film layer 4, a source contact region 31, a drain contact region 32, a gate insulating layer 5, a gate electrode layer 6 and a dielectric layer 7, and a planarization layer 8 in a serial. The gate electrode layer 6 is located right above the low temperature poly-silicon layer 3. The source contact region 31, the drain contact region 32, and the low temperature poly-silicon layer 3 are located at the same layer, and the source contact region 31 and the drain contact region 32 are located at the opposite ends of the low temperature poly-silicon layer 3.

Step S02 is to coat the photoresist material on the film layer to form the photoresist layer 5, and execute an exposure process to the photoresist layer 5 by using a mask 10. The mask 10 includes a central region 101 and a boundary region 102 surrounding the central region. The thickness of the central region is greater than that of the boundary region. As shown in FIG. 2, by having the thickness of the central region greater than that of the boundary region during the exposure process applied to the photoresist layer, the loading effect during the development process can be cancelled to uniformize a thickness of the film layer 4.

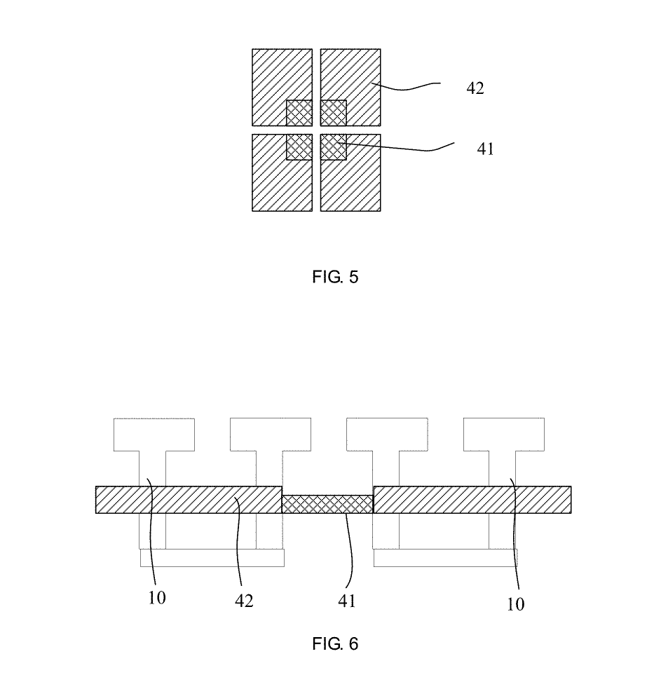

Please refer to FIG. 5, which is a top view of the film layer 4 formed on the substrate by using the mask 10 provided in accordance with an embodiment of the present invention. The shape of the film layer 4 is corresponding to the shape of the mask 10. As shown in FIG. 5, because the film layer 4 includes four sub-regions placed in an array to form a central cross at the center, in correspondence with the film layer 4, the mask 10 also includes four sub-masks placed in an array to form a central cross at the center, the central region 101 of the mask includes the regions of the four sub-masks corresponding to the center of the central cross, that is, the central region 101 includes four sub-regions. The boundary region 102 is also divided into four sub-regions by the central cross,

In the present embodiment, the central region 101 of the mask 10 is opaque, but the boundary region 102 of the mask is transparent.

Concretely speaking, transmittance of the boundary region of the mask is greater than 0.2 but smaller than 0.6.

Furthermore, the manufacturing method further comprises the steps of developing, ashing, and striping the film layer after the exposure process. Wherein the film layer is formed by using a half-tone technology.

Wherein, the thickness difference between the central region 101 and the boundary region 102 of the mask 10 would be changed based on the variation of transmittance in mask design.

After the aforementioned steps, the height of the central region 41 of the film layer 4 of the substrate and that of the boundary region 42 would be kept at the same level.

Step S03 is to apply the developing, ashing, and striping processes to the photoresist layer after the exposure process to form the thin film transistor.

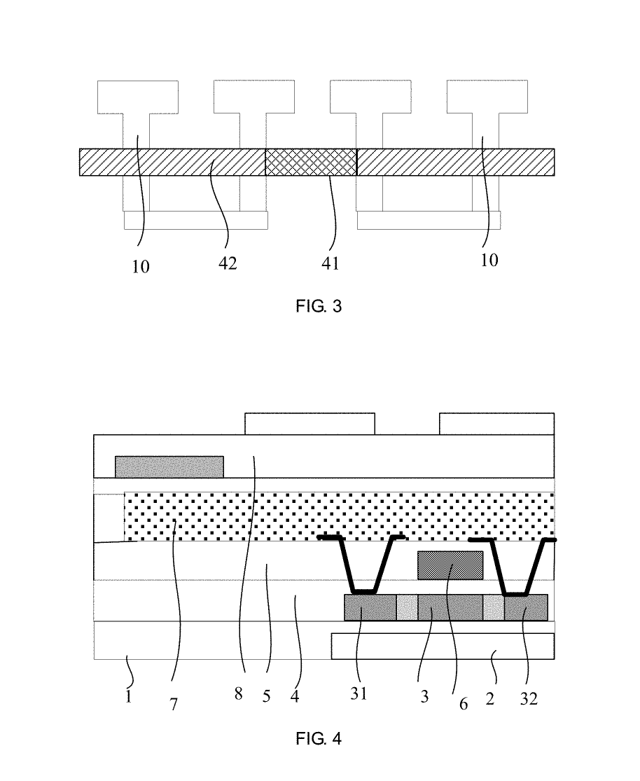

In the present invention, the mask has a thicker central region to slow down the development process so as to synchronize the development speed of the central region and the boundary region. As shown in the structural schematic view of FIG. 3, after the exposure and development processes, the loading effect happened to the film layer on the top of the central region during the development process is exactly cancelled by the thicker mask, such that the position change of the film layer becomes smaller during the development process to synchronize with the position change of the film layer in the boundary region so as to uniformize the central region film layer 41 and the boundary region film layer 42.

Another thin film transistor is provided in accordance with a second aspect of the present invention. The thin film transistor can be manufactured by using the manufacturing method described in the aforementioned embodiment. The structure of the thin film transistor can be referred to the structure of the thin film transistor shown in FIG. 4, wherein the thin film transistor includes a substrate 1, and a buffer layer 2, a low temperature poly-silicon layer 3, a film layer 4, a source contact region 31, a drain contact region 32, a gate insulating layer 5, a gate electrode layer 6 and a dielectric layer 7, a planarization layer 8 stacked on the substrate 1 in a serial. The gate electrode layer 6 is located right above the low temperature poly-silicon layer 3. The source contact region 31, the drain contact region 32, and the low temperature poly-silicon layer 3 are located at the same layer, and the source contact region 31 and the drain contact region 32 are located at the opposite ends of the low temperature poly-silicon layer 3.

In this embodiment of the present invention, the source electrode is in contact with the surface of the low temperature poly-silicon layer 3 away from the buffer layer through the source contact region 31, and the drain electrode is in contact with the surface of the low temperature poly-silicon layer 3 away from the buffer layer through the drain contact region 32. Because the lithography process of the present embodiment uses the mask 10 with a thicker central region to cancel the loading effect happened during the development process exactly such that the uniformity of the film layer 4 on the substrate can be guaranteed.

FIG. 6 is a structural schematic view of the substrate after the exposure treatment by using the conventional technology. In the conventional technology, because the photoresist layer in the central region of the substrate is not effectively treated by the photoresist development process, the central cross may suffer the loading effect, i.e. the developer solution in the central region has a higher concentration, which may generate a greater position change of the film layer and make the line width smaller within the same development period. In contrast, the thin film transistor provided in the present invention uses the half-tone technology to generate a mask with uneven thickness in the central region and the boundary region, so as to cancel the loading effect during the development process to guarantee the uniformity of the film layer on the substrate, and thus the problems of uniformity anomaly and electric anomaly of product yield can be prevented.

The foregoing contents are detailed description of the disclosure in conjunction with specific preferred embodiments and concrete embodiments of the disclosure are not limited to the description. For the person skilled in the art of the disclosure, without departing from the concept of the disclosure, simple deductions or substitutions can be made and should be included in the protection scope of the application.

What is claimed is:

1. A manufacturing method of a thin film transistor, comprising the steps of:
providing a substrate which includes a film layer;
coating a photoresist material on the film layer to form a photoresist layer; and
executing an exposure process to the photoresist layer by using a mask, wherein the mask includes a central region and a boundary region surrounding the central region, a thickness of the central region is greater than that of the boundary region, the mask includes four sub-masks placed in an array to form a central cross therebetween, the central region includes regions of the four sub-masks corresponding to a center of the central cross, the boundary region is divided into four sub-regions by the central cross, and by having the thickness of the central region greater than that of the boundary region during the exposure process applied to the photoresist layer, loading effect happened during a development process is cancelled to uniformize a thickness of the film layer.

2. The manufacturing method of claim 1, wherein the central region of the mask is opaque, and the boundary region of the mask is transparent.

3. The manufacturing method of claim 2, wherein transmittance of the boundary region of the mask is greater than 0.2 and small than 0.6.

4. The manufacturing method of claim 3, further comprising the steps of:
developing, ashing, and striping the film layer after the exposure process.

5. The manufacturing method of claim 1, wherein the film layer is formed by using a half-tone technology.

6. A mask, comprises a central region and a boundary region surrounding the central region, wherein a thickness of the central region is greater than that of the boundary region, the mask includes four sub-masks placed in an array to form a central cross therebetween, the central region includes regions of the four sub-masks corresponding to a center of the central cross, the boundary region is divided into four sub-regions by the central cross, and by having the thickness of the central region greater than that of the boundary region during the exposure process applied to the photoresist layer, loading effect happened during an development process is cancelled to uniformize a thickness of the film layer.

7. The mask of claim 6, wherein the central region of the mask is opaque, and the boundary region of the mask is transparent.

8. The mask of claim 7, wherein transmittance of the boundary region of the mask is greater than 0.2 and small than 0.6.

9-10. (canceled)
